(19) United States
(12) Patent Application Publication
(10) Pub. No.: US 2017/0221927 A1
(43) Pub. Date: Aug. 3, 2017

(54) DISPLAY SUBSTRATE AND WEARABLE DEVICE

(71) Applicant: BOE TECHNOLOGY GROUP CO., LTD., Beijing (CN)

(72) Inventor: WENBO LI, Beijing (CN)

(73) Assignee: BOE TECHNOLOGY GROUP CO., LTD., Beijing (CN)

(21) Appl. No.: 15/328,660

(22) PCT Filed: Mar. 25, 2016
(86) PCT No.: PCT/CN2016/077342

§ 371 Date: Jan. 24, 2017

(30) Foreign Application Priority Data
Sep. 15, 2015 (CN) 201510587642.0

(51) Int. Cl. H01L 27/12; G04G 9/00

(52) U.S. Cl. CPC H01L 27/1218; G04G 9/00

(57) ABSTRACT

A display substrate and a wearable device are disclosed. The display substrate includes a display region and a peripheral region, and the display region has a shape of circle. A shape of outer edge of the peripheral region is a shape enclosed by straight lines and curves, or the outer edge of the peripheral region is of polygon. The outer edge of the display substrate is of non-circle, but is a shape enclosed by straight lines and curves or is of polygon, so that enough space is remained for arrangement of the gate driver circuit and the source driver circuit so that a width of the peripheral region in a corresponding direction is reduced and the area of the display substrate is reduced. Meanwhile, it facilitates to improve utilization in cutting glass substrates.

### TECHNICAL FIELD

The present invention relates to the display technical field, particularly, to a display substrate and a wearable device.

### BACKGROUND

For wearable devices such as a smart swatch etc., a circle shaped screen meets characteristics of the product and aesthetics of humans better. Thus, a circle shaped display substrate is usually adopted as a display screen in the wearable devices such as a smart watch.

### SUMMARY

The invention aims to at least solve one of technical problems in related arts. A display substrate and a wearable device are proposed with a small area of the display substrate so as to further reduce a volume of the wearable device.

In order to achieve purposes of the invention, a display substrate is provided. The display substrate comprises a display region and a peripheral region, the display region is of circle, a shape of outer edge of the peripheral region is a shape enclosed by straight lines and curves, or the outer edge of the peripheral region is of polygon.

The shape of the outer edge of the peripheral region is the shape enclosed by the straight lines and curves, the straight lines comprise a plurality of straight line segments, the curves comprise a plurality of curve segments, the plurality of curve segments are located on a same circle, and a circle center of the circle is coincided with a circle center of the display region.

A gate driver circuit and/or a source driver circuit are provided in a region of the peripheral region close to the curve.

In the outer edge of the peripheral region, two ends of each of the plurality of the straight line segments are connected with curve segments.

Radian corresponding to each of the plurality of the curve segments is no more than 45 degrees.

The outer edge of the peripheral region is of polygon, and a number of edges of the polygon is no less than 5.

A gate driver circuit and/or a source driver circuit are provided in a region of the peripheral region close to vertices of the polygon.

In another technical solution, a wearable device is provided. The wearable device comprises above mentioned display substrate.

A number of the display substrates are 2, the two display substrates are an array substrate and a counter substrate respectively, and the array substrate and the counter substrate are cell assembled.

A projection of the counter substrate on a plane at which the array substrate is positioned, is located within the array substrate.

The wearable device is a smart watch.

The invention has following technical effects:

The outer edge of the display substrate provided by the invention is of non-circle, but is a shape enclosed by straight lines and curves or is of polygon, so that enough space is remained for arrangement of the gate driver circuit and the source driver circuit and a width of the peripheral region in a corresponding direction is reduced, in order that the area of the display substrate is reduced. Meanwhile, it facilitates to improve utilization in cutting glass substrates.

The wearable device provided by the invention adopts the display substrate provided by above mentioned embodiments. Because the area of the display substrate is reduced, a volume of the wearable device can be reduced.

### BRIEF DESCRIPTION OF THE DRAWINGS

Accompanying drawings are provided to facilitate further comprehension of the invention, and constitute a portion of the specification. The accompanying drawings explain the invention along with following embodiments and do not limit the invention. In the drawings:

FIG. 1 is a schematic diagram of cutting square shaped display screen and a circle shaped display;

FIG. 2 is a schematic diagram of the circle shaped display screen;

FIG. 3 is a schematic diagram of at least one embodiment of display substrate provided by the invention, which illustrates a superposed state of an array substrate and a counter substrate;

FIG. 4 is a schematic diagram of the at least one embodiment of the display substrate illustrated in FIG. 3, which illustrates the superposed state of the array substrate and the counter substrate;

FIG. 5 is a schematic diagram of cutting the counter substrate of the display substrate illustrated in FIG. 3, and the array substrate and the counter substrate of the display substrate illustrated in FIG. 4;

FIG. 6 is a schematic diagram of cutting the array substrate of the display substrate illustrated in FIG. 3;

FIG. 7 is a schematic diagram of at least one embodiment of a display substrate provided by the invention;

FIG. 8 is a schematic diagram of the at least one embodiment of the display substrate illustrated in FIG. 7;

FIG. 9 is a schematic diagram of arrangement of driver circuits of the display substrate illustrated in FIG. 8;

FIG. 10 is a schematic diagram of the at least one embodiment of the display substrate illustrated in FIG. 7.

Reference signs list: 1: display region; 2: peripheral region; 3: array substrate; 4: counter substrate.

### DETAILED DESCRIPTION

The technical solutions of the embodiments will be described in more details in connection with the drawings in following. It should be noted that, the described embodiments are only for illustrating and explaining the invention, and thus are not limitative of the invention.

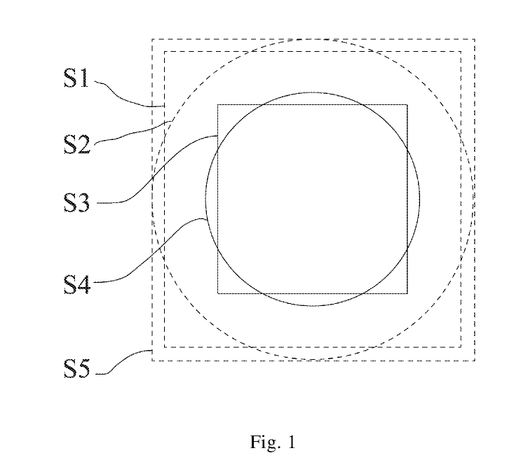

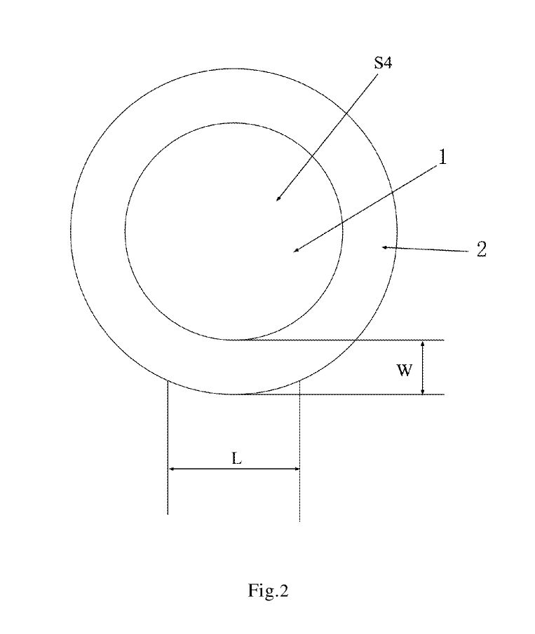

A circle shaped display screen belongs to a heterotypic screen which has many differences from a normal square shaped display screen, for example, cutting manner in fabrication process. As illustrated in FIGS. 1, S1 and S2 indicate cutting straight lines, and S3 and S4 indicate effective display regions. The effective display region is the region S3 for the square shaped display screen, and in cutting, cutting can be performed along the cutting straight line S1. But, the effective display region is the region S4 for the circle shaped display screen, and in cutting, cutting can be performed along the cutting straight line S2 normally. The cut circle shaped display screen is illustrated in FIG. 2, and it can comprise a display region 1 and a peripheral region 2. Pixel structures which are configured to display are provided in the display region, and driver circuits which drive the pixel structures to display are provided in the peripheral region. The driver circuit comprises a gate driver circuit and a source driver circuit normally.

In FIG. 1, S3 has a same area as that of S4. A distance form edge of S2 to S1 is same as a distance from edge of S4 to S2. It can be seen from FIG. 1 that an area (i.e. the area of S5) of the glass substrate occupied by the circle shaped display screen is larger than an area (i.e. the area of S1) of the glass substrate occupied by the squared shaped display screen, if the resultant display screen after cutting have a same area. Obviously, in the above mentioned manner of cutting the circle shaped display screen, utilization of the glass substrate is lower.

In addition, in FIG. 2, the peripheral region 2 is required to have a width W and a length L to accommodate driver circuits and be configured to wiring. However, a region of the peripheral region outside L should maintain the width W due to the limitation of a shape of outer edge (i.e. the outer edge is maintained as a circle), so that the peripheral region 2 has a large width and area, and most of the area leaves unused and is not utilized efficiently. Thus, the area of the circle shaped display screen is large, and thus a volume of the smart device such as a smart watch which adopts the circle shaped display screen is large.

The invention provides embodiments of a display substrate. The display substrate can be a color film substrate, an array substrate or a backlight plate etc., and can also be an electroluminescent display panel.

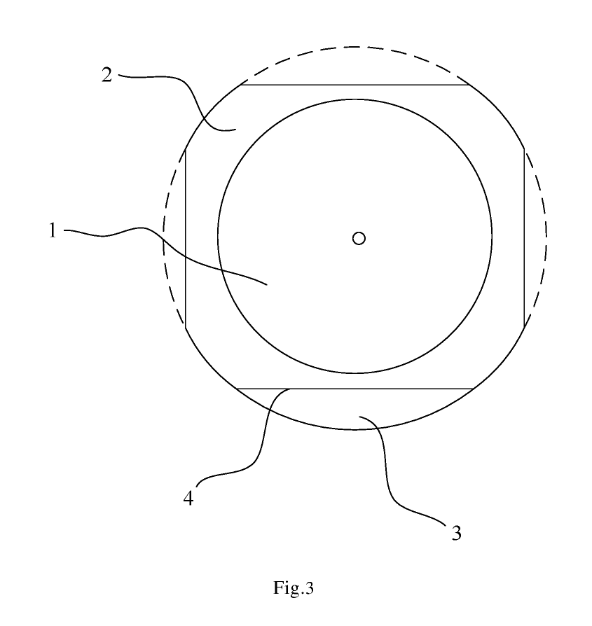

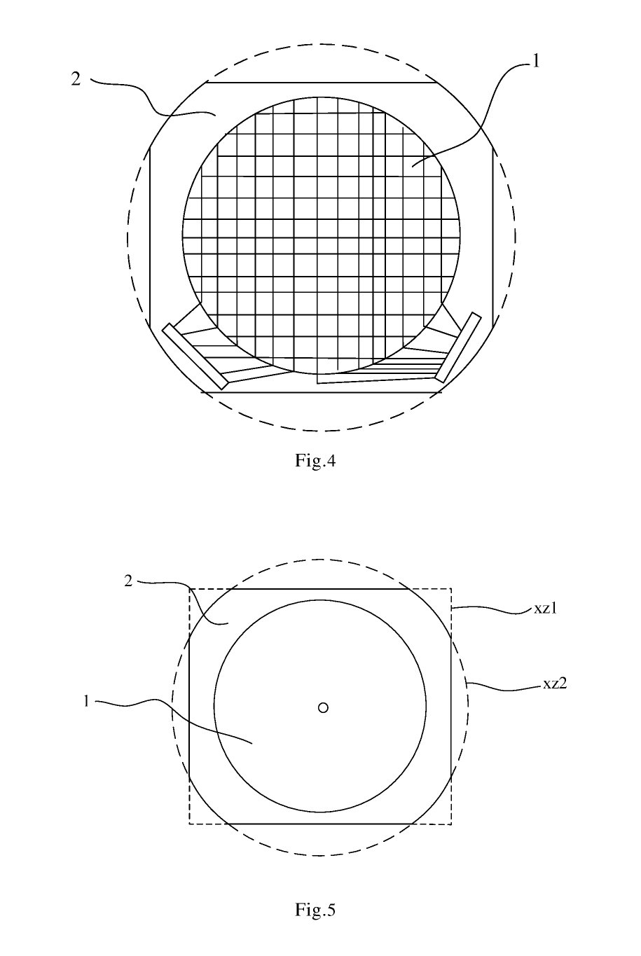

FIG. 3 is a schematic diagram of a first embodiment of the display substrate provided by the invention, and this diagram illustrates a superposed state of an array substrate and a counter substrate. FIG. 4 is a schematic diagram of an alternative embodiment of the display substrate illustrated in FIG. 3, and this diagram also illustrates the superposed state of the array substrate and the counter substrate. As illustrated in FIGS. 3 and 4, the display substrate comprises a display region 1 and a peripheral region 2, the display region is of circle, and pixel structures which are configured to display an image are provided in the display region 1.

If the display substrate is an array substrate or an electroluminescent display panel, peripheral circuits can be provided in the peripheral region 2.

The peripheral circuit can be at least one of a gate driver circuit, a source driver circuit, a timing controller etc., to drive the pixel structures in the display region 1, in order to perform displaying, or the peripheral circuit can be further provided with sensors, powers, and the like.

In the embodiment, outer edge of the display substrate (i.e. the outer edge of the peripheral region 2) is of non-circle. For instance, it can be a shape enclosed by straight lines and curves, and its particular shape can be illustrated as FIGS. 3 and 4 (of course, it is not limited to the shapes illustrated in FIGS. 3 and 4).

In the embodiments illustrated in FIGS. 3 and 4, straight lines for forming the outer edge of the peripheral region 2 comprise a plurality of straight line segments, and curves for forming the outer edge of the peripheral region 2 comprise a plurality of curve segments. The curve segments are located on a same circle and a circle center of the circle is coincided with a circle center of the display region. The plurality of straight line segments and the plurality of curve segments are connected to enclose the outer edge of the peripheral region 2. Dotted straight lines shown in FIGS. 3 and 4 are only for illustration that the plurality of curve segments are located on a same circle, that is, the plurality of curve segments and the dotted straight line segments form the circle.

It can be seen from FIGS. 3 and 4 that, a distance from the curve segment to the circle center of the display region 1 is larger than a distance from the straight line segment to the circle center of the display region, which indicates that a width of the region corresponding to the curve segment is larger, and a width of the region corresponding to the straight line segment is smaller in the peripheral region 2. Therefore, in the embodiment, peripheral circuits such as the gate driver circuit, the source driver circuit, the timing controller etc. can be provided in the regions corresponding to the curve segments. Compared to related arts, in case of providing the same space configured to accommodate the gate driver circuit and the gate driver circuit and accommodate wirings on the display substrate, a width of other regions (regions corresponding to straight line segments) can be reduced, to reduce an area of the display substrate. For the wearable device which adopts the display substrate of the embodiment as the display screen, a volume of the wearable device can be reduced correspondingly on premise that it comprises the same circuit structures or has the same functions.

The display substrate can comprise one of the array substrate 3 and the counter substrate 4 which can be cell assembled.

In preparing the display substrate, patterns of the array substrate 3 and the counter substrate 4 are prepared on two glass substrates, respectively, and then the glass substrates are cut into multiple blocks of array substrates 3 and multiple blocks of counter substrates 4. Finally, the array substrate 3 and the counter substrate 4 which are prepared completely are cell assembled, to obtain the display panel.

In the embodiment illustrated in FIG. 3, the array substrate 3 are enclosed by three straight line segments and three curve segments, and the shape of the array substrate 3 is a shape formed by a circle being cut off portions along straight lines at the top, left and right sides. The counter substrate 4 is enclosed by four straight line segments and four curve segments, and the shape of the counter substrate 4 is a shape formed by a circle being cut off portions along straight lines at the top, bottom, left and right sides, as illustrated in FIG. 3. In the display substrate illustrated in FIG. 3, a projection of the counter substrate 4 on a plane at which the array substrate 3 is located is within the array substrate 3. In the embodiment illustrated in FIG. 4, both of the array substrate 3 and the counter substrate 4 are enclosed by four straight line segments and four curve segments. The shape of them is a shape formed by a circle being cut off portions along straight lines from the top, bottom, left and right sides, and the shape of the array substrate 3 is corresponding to the shape of the counter substrate 4.

In the embodiments illustrated in FIGS. 3 and 4, two ends of each straight line segment of the outer edge of the display substrate are connected with the curve segments of the outer edge of the display substrate. Furthermore, optionally, radian corresponding to each curve segment is no greater than 45 degrees.

One implementation is that: the outer edge of the display substrate is enclosed by four straight line segments having the same length and four curve segments having the same length and the same radian, and the curve segment and the straight line segment are provided alternately. Optionally, the radian corresponding to the curve segment is in a range from 20 degrees to 30 degrees. Distances from the circle center of the circle to respective straight line segments are the same, and distances from the circle center of the circle to respective curve segments are the same.

Another implementation is that: the outer edge of the display substrate are enclosed by three straight line segments having the same length, two curve segments having the same length and radian and another curve segment. The curve segments and the straight line segments are provided alternately. Two of the three straight line segments are provided in parallel, and the other straight line segment is perpendicular to the two parallel straight line segments. Optionally, the two curve segments having the same length and radian correspond to a radian range from 20 degrees to 30 degrees respectively. Distances from the circle center of the display region to respective straight line segments are the same. The radian of the two curve segments having the same length and radian is less than the radian of the other curve segment.

For the display substrate formed by the above mentioned implementations, the display substrate formed by the first implementation can be used as a color film substrate, and the display substrate formed by the second implementation substrate can be used as an array substrate. Of course, the display substrate formed by the first implementation can not only be used as the color film substrate and but also be used as the array substrate. The color film substrate and the array substrate which are cell assembled can form the display panel.

In a process of preparing the display substrate illustrated in FIGS. 3 and 4, when the glass substrate are cut into the array substrate 3 and the counter substrate 4, they can be cut along shapes of the array substrate 3 and the counter substrate 4. Such cutting manner can cut the array substrate 3 and the counter substrate 4 directly, without a secondary cutting. But, because shapes of the array substrate 3 and the counter substrate 4 are irregular, it is difficult to cut.

Therefore, when the glass substrates are cut into the array substrate 3 and the counter substrate 4, the following cutting manner can be adopted: firstly, a circle is cut on the glass substrate; then portions are cut off from the circle along three straight lines on top, left and right of the circle (for the array substrate of the embodiment illustrated in FIG. 3) or portions are cut off along four straight lines on top, bottom, left and right of the circle (for the counter substrate of the embodiment illustrated in FIG. 3 and the array substrate and the counter substrate of the embodiment illustrated in FIG. 4), to obtain the corresponding array substrate 3 and the counter substrate 4. Such cutting manner needs two times of cutting, but the shape after each cutting is done is regular, and thus it is easy to cut.

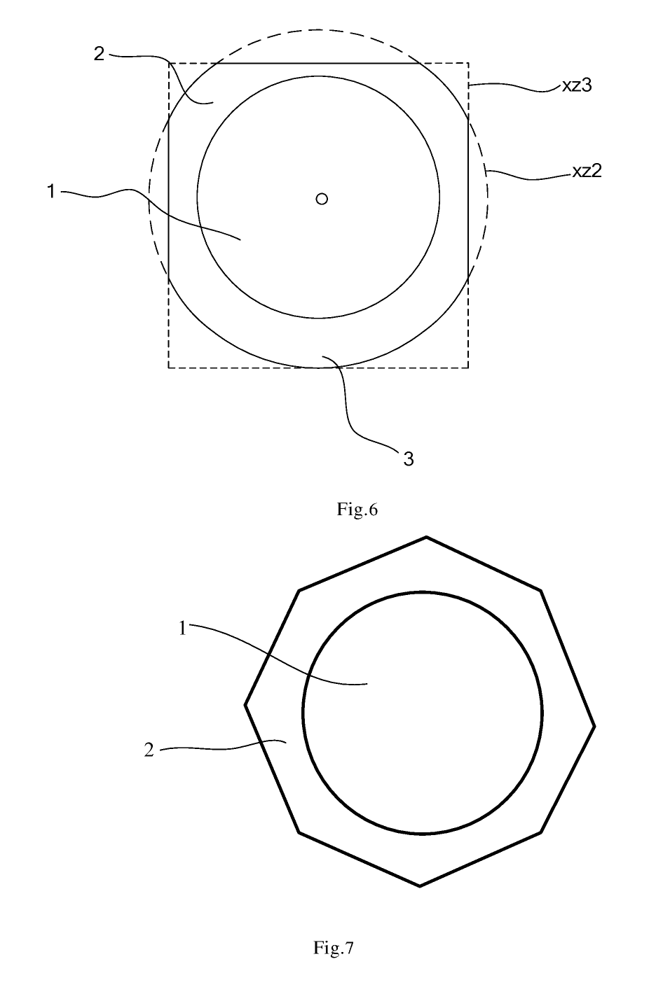

In addition, a rectangular, instead of a circle, can be firstly cut on the glass substrates in the process of two times of cutting to obtain the array substrate 3 and the counter substrate 4. For example, for the counter substrate 4 of the embodiment illustrated in FIG. 3 and the array substrate 3 and the counter substrate 4 of the embodiment illustrated in FIG. 4, as illustrated in FIG. 5, a rectangular xz1 can be cut on the glass substrate firstly, and then cutting is performed along circle xz2, to obtain desired array substrate 3 and the counter substrate 4. In addition, for the array substrate 3 of the embodiment illustrated in FIG. 3, as illustrated in FIG. 6, a rectangular xz3 can be cut on the glass substrate firstly, and then cutting is performed along the rectangular xz2, to obtain the desired array substrate 3.

FIG. 7 is a schematic diagram of a second embodiment of a display substrate provided by the invention. As illustrated in FIG. 7, this embodiment is different from above mentioned first implementation that: the outer edge of the peripheral region 2 is of polygon instead of a shape enclosed by straight line segments and curve segments. Particularly, a number of edges of the polygon is no less than 5. In addition, respective vertices of the polygon is far from the display region, so that a region between the vertices and the display region is large, and optionally, the peripheral circuits such as the gate driver circuit and the source driver circuit etc. are provided in the region. Therefore, the embodiment can achieve the same technical effects as that of the first implementation.

As illustrated in FIG. 7, the outer edge of the display substrate is of regular polygon, particularly, regular octagon. In cutting the array substrate and the counter substrate of the display panel, respective implementations of the above embodiments can be adopted to perform cutting processes.

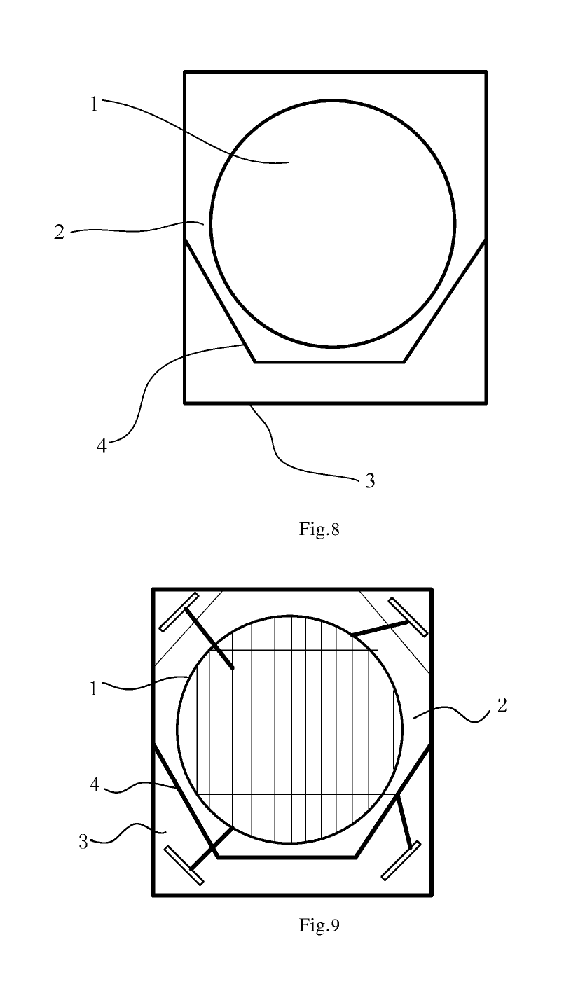

In addition, the edge of the display substrate is not limited to regular polygon, and it can also be other shapes. For example, as illustrated in FIG. 8, the array substrate 3 of the display substrate can be of a regular square, but the counter substrate 4 of the display substrate can be of hexagon. That is, the shape of the counter substrate 4 is obtained by cutting two adjacent angles and cutting along an edge between the two adjacent angles on the basis of the square shape of the array substrate 3, to form the hexogen as illustrated in FIG. 8, so that a projection of the counter substrate 4 on the array substrate 3 is located within the array substrate 3, that is, the area of the counter substrate 4 is less than the area of the array substrate 3. For the display substrate as illustrated in FIG. 8, the gate driver circuit and the source driver circuit of the display substrate can be provided in the region of the array substrate 3 outside the projection of the counter substrate 4, and be provided in a region on the array substrate 3 corresponding to angles of the counter substrate 4 which are not cut, as illustrated in FIG. 9. Because the area of the counter substrate 4 is small, utilization of the glass substrate can be improved in cutting.

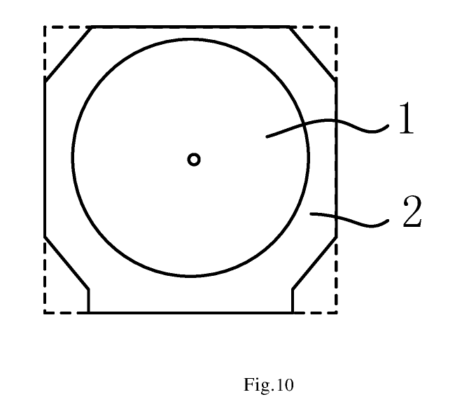

In addition, the display substrate can also be of polygon, as illustrated in FIG. 10. In FIG. 10, the display substrate is obtained by cutting off a triangle from two adjacent angles of a square, and cutting off a right-angled trapezoid from the other two angles of the square. For the shape illustrated in FIG. 10, in cutting the display substrate on the glass substrate, the cutting can be performed along a pattern illustrated by dotted straight lines in the figure firstly, and then two triangles and two right-angled trapezoids are cut off from four angles respectively, to obtain the display substrate illustrated in FIG. 10.

The outer edge of the display substrate provided by the invention is of non-circle, and is of a shape which is enclosed by straight lines and curves or of a polygon, so that enough space is remained for arrangement of the gate driver circuit and the source driver circuit so as to reduce a width of the peripheral region in a corresponding direction, and the area of the display substrate is reduced. Meanwhile, it facilitates to improve utilization in cutting glass substrates.

The invention further provides an embodiment of a wearable device. In the embodiment, the wearable device comprises at least one display substrate of above mentioned embodiments.

The wearable device comprises two display substrates. One of them is an array substrate, the other is a counter substrate or cover glass, and they are cell assembled. The array substrate can be a liquid crystal display substrate or an electroluminescent display array substrate. The array substrate can be any kind of display substrates shown in the application, and the counter substrate or cover glass can be any kind of display substrates shown in the application.

Optionally, the projection of the counter substrate on a plane at which the array substrate is positioned is located within the array substrate.

Optionally, the wearable device is a smart watch.

The wearable device provided by the invention adopts the display substrate provided by above mentioned embodiments. Because the area of the display substrate is reduced, a volume of the wearable device can be reduced.

It is should be noted that, above mentioned embodiments are only for illustrating principles of the invention and are illustrative embodiments. But the invention is not limited to this. For those skilled in this art, any change or variation can be made to the embodiments without a departure from the spirit and scope of the invention. These changes or variations are intended to be included within the protection scope of the invention.

1. A display substrate, comprising a display region and a peripheral region, the display region having a shape of circle, wherein, a shape of outer edge of the peripheral region is a shape enclosed by straight lines and curves, or the outer edge of the peripheral region has a shape of polygon.

2. The display substrate of claim 1, wherein, the shape of the outer edge of the peripheral region is the shape enclosed by the straight lines and curves, the straight lines comprise a plurality of straight line segments, the curves comprise a plurality of curve segments, the plurality of curve segments are located on a same circle, and a circle center of the circle is coincided with a circle center of the display region.

3. The display substrate of claim 2, wherein, in the outer edge of the peripheral region, two ends of each of the straight line segments are connected with curve segments.

4. The display substrate of claim 3, wherein, a gate driver circuit and/or a source driver circuit are provided in a region of the peripheral region close to the curve.

5. The display substrate of claim 2, wherein, a radian corresponding to each of the curve segments is no more than 45 degrees.

6. The display substrate of claim 1, wherein, the outer edge of the peripheral region has a shape of polygon, and a number of edges of the polygon is no less than 5.

7. The display substrate of claim 6, wherein, a gate driver circuit and/or a source driver circuit are provided in a region of the peripheral region close to vertices of the polygon.

8. A wearable device, wherein, the wearable device comprises the display substrate of claim 1.

9. The wearable device of claim 8, wherein, the display substrate includes two display substrates, the two display substrates are an array substrate and a counter substrate respectively, and the array substrate and the counter substrate are cell assembled.

10. The wearable device of claim 9, wherein, a projection of the counter substrate on a plane at which the array substrate is positioned, is located within the array substrate.

11. The wearable device of claim 8, wherein, the wearable device is a smart watch.

12. The wearable device of claim 8, wherein, the shape of the outer edge of the peripheral region is the shape enclosed by the straight lines and curves, the straight lines comprise a plurality of straight line segments, the curves comprise a plurality of curve segments, the plurality of curve segments are located on a same circle, and a circle center of the circle is coincided with a circle center of the display region.

13. The wearable device of claim 12, wherein, in the outer edge of the peripheral region, two ends of each of the straight line segments are connected with curve segments.

14. The wearable device of claim 13, wherein, a gate driver circuit and/or a source driver circuit are provided in a region of the peripheral region close to the curve.

15. The wearable device of claims 12, wherein, a radian corresponding to each of the curve segments is no more than 45 degrees.

16. The wearable device of claim 8, wherein, the outer edge of the peripheral region has a shape of polygon, and a number of edges of the polygon is no less than 5.

17. The wearable device of claim 16, wherein, a gate driver circuit and/or a source driver circuit are provided in a region of the peripheral region close to vertices of the polygon.
